(19) United States
(12) Patent Application Publication
(10) Pub. No.: US 2025/0019832 A1
(43) Pub. Date: Jan. 16, 2025

(54) IMPROVEMENTS IN CHEMICAL VAPOR DEPOSITION SYSTEMS

(71) Applicant: CVD Equipment Corporation, Central Islip, NY (US)

(72) Inventors: William S. Linss, East Patchogue, NY (US); John B. Feraca, Shirley, NY (US)

(21) Appl. No.: 18/711,363

(22) PCT Filed: Nov. 18, 2022
(86) PCT No.: PCT/US2022/050351

§ 371 Date: May 17, 2024

Related U.S. Application Data
(60) Provisional application No. 63/282,061, filed on Nov. 22, 2021.

(51) Int. Cl. C23C 16/46; C23C 16/458; C23C 16/50; C23C 16/52

(52) U.S. Cl. CPC C23C 16/463; C23C 16/4584; C23C 16/4586; C23C 16/50; C23C 16/52

(57) ABSTRACT

Chemical Vapor Deposition (CVD) systems with DC, RF, IF (intermediate frequency) and/or microwave plasma have processing chambers incorporate structure to provide improved temperature control, uniform distribution of the process gas, and plasma distribution between the positive electrode and grounded wafer. The temperature of a rotating wafer chuck during a chemical vapor deposition process may be controlled by a programmable logic controller that includes algorithms for controlling a temperature of the rotating wafer chuck.

### CROSS-REFERENCE TO RELATED APPLICATIONS

This application claims the benefit of, and priority to, U.S. Provisional Patent Application No. 63/282,061 filed on Nov. 22, 2021, the entire contents of which are hereby incorporated herein by reference.

### TECHNICAL FIELD

The present disclosure generally relates to chemical vapor deposition (CVD) systems. More specifically, the present disclosure relates to CVD systems with DC, RF, IF (intermediate frequency) and/or microwave plasma having processing chambers that incorporate structure to provide for improved temperature control, uniform distribution of the process gas, and plasma distribution between the positive electrode and grounded wafer.

### BACKGROUND

Unless otherwise indicated herein, the materials described in this section are not prior art to the claims in this application and are not admitted as being prior art by inclusion in this section.

Chemical vapor deposition systems are used to deposit a coating upon a substrate (e.g., a wafer). The substrate may be supported by a rotating wafer chuck. Due to the small size of conventional process chambers, handling of substrates in and out of the chamber may present technical challenges, particularly when the substrate is being positioned on a rotating chuck. Adequate grounding of the substrate while mounted in the rotating chuck may also present challenges. In addition, temperature control during the chemical vapor deposition impacts the quality of the deposited coating. Wafer temperature may increase due to energy provided by plasma (typically in the range of 200-600 Watts of power) and may exceed a desired value required for the CVD process, and cooling may be required to maintain temperature control for the rotating wafer chuck.

### SUMMARY

Systems and apparatus for controlling a temperature of a rotating wafer chuck of a chemical vapor deposition system (such as, for example, a parallel-plate plasma enhanced chemical vapor deposition system) are described herein.

In one aspect, a temperature control apparatus in accordance with the present disclosure includes a rotating wafer chuck having at least one rotationally divided heat zone in communication with a heating element, and at least one rotationally divided cool zone in communication with a cooling element. In embodiments, the rotating wafer chuck may include an inner heat zone, an outer heat zone, and a middle heat zone. In embodiments, the rotating wafer chuck may include an inner cool zone, an outer cool zone, and a middle cool zone. In embodiments, each of the inner cool zone, the outer cool zone, and the middle cool zone may include an optical pyrometer port or some other means of temperature measurement.

In another aspect, a system for controlling a temperature during chemical vapor deposition in accordance with the present disclosure includes a rotating wafer chuck, a cooling element, a heating element, a temperature sensor, and a programmable logic controller. The rotating wafer chuck includes at least one rotationally divided heat zone in communication with the heating element and at least one rotationally divided cool zone in communication with the cooling element. The programmable logic controller is in communication with the cooling element, the heating element, the temperature sensor, and the rotating wafer chuck, and includes a processor and a memory storing instructions which, when executed by the processor, controls a temperature of the rotating wafer chuck utilizing at least one of the heating element or the cooling element. In embodiments, the instructions, when executed by the processor, may control a temperature of the rotating wafer chuck utilizing the heating element and the cooling element simultaneously. In embodiments, the instructions, when executed by the processor, may set the cooling element to a constant temperature or constant power setting and modulates the heating element with enough power to overcome the cooling effect of the cooling element. In embodiments, the rotating wafer chuck may be made at least in part of SiC coated graphite. In embodiments, the cooling element may be a cooling plate. In embodiments, the heating element may include a two zone SiC coated graphite heater. In aspects, during chemical vapor deposition, the chemical vapor deposition system may generate one or more of: DC plasma, pulsed DC plasma, RF plasma, pulsed RF plasma, intermediate frequency (IF) plasma, pulsed IF plasma, mixed DC and RF plasma, mixed DC and IF plasma, mixed IF and RF plasma, mixed DC and RF and IF plasma, microwave plasma, or microwave plasma mixed with one or more of DC, RF, or IF plasma.

### BRIEF DESCRIPTION OF THE FIGURES

The foregoing and other features of the present disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings, in which:

FIG. 1 shows an illustrative system for chemical vapor deposition that may incorporate various aspects of the presently disclosed features;

FIG. 2 shows the process chamber of the system of FIG. 1 with the cover removed to show internal structures thereof;

FIG. 3 is a cross-sectional view of the retractable showerhead mounted to the process chamber;

FIG. 4 shows the process chamber of the system of FIG. 1 with the showerhead retracted and the wafer and wafer grounding ring in the wafer unload position;

FIG. 5 shows the process chamber of the system of FIG. 1 with the showerhead lowered and the wafer and wafer grounding ring in the process position;

FIG. 6 is a side perspective view of the wafer grounding ring contacting the wafer when the wafer grounding ring is in the process position;

FIG. 6A shows the detail of the wafer grounding ring contacting the wafer when the wafer grounding ring is in the process position;

FIG. 6B shows the detail of the wafer grounding ring contacting the rotation chuck when the wafer grounding ring is in the process position;

FIG. 7 shows an alternative embodiment where the process chamber includes a lower sealing plate such that the lift plate is located outside the reaction zone;

FIG. 8 schematically depicts a backside view of a rotating wafer chuck according to an embodiment of the present disclosure;

FIG. 9 schematically illustrates a side cross sectional view of a rotating wafer chuck according to an embodiment of the present disclosure; and

FIG. 10 illustrates a bottom perspective view of an example system for cooling a rotating wafer chuck according to an embodiment of the present disclosure.

### DETAILED DESCRIPTION

The terminology used herein is for the purpose of describing particular embodiments only and is not intended to be limiting of the present disclosure. As used herein, the term “and/or” includes any and all combinations of one or more of the associated listed items. As used herein, the singular forms “a,” “an,” and “the” are intended to include the plural forms as well as the singular forms, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

Unless otherwise defined, all terms (including technical and scientific terms) used herein have the same meaning as commonly understood by one having ordinary skill in the art to which this disclosure belongs. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

In describing the present disclosure, it will be understood that a number of systems, methodologies, techniques and steps are disclosed. Each of these has individual benefit and each can also be used in conjunction with one or more, or in some cases all, of the other disclosed techniques. Accordingly, for the sake of clarity, this description will refrain from repeating every possible combination of the individual steps in an unnecessary fashion.

Nevertheless, the specification and claims should be read with the understanding that such combinations are entirely within the scope of the disclosure and the claims.

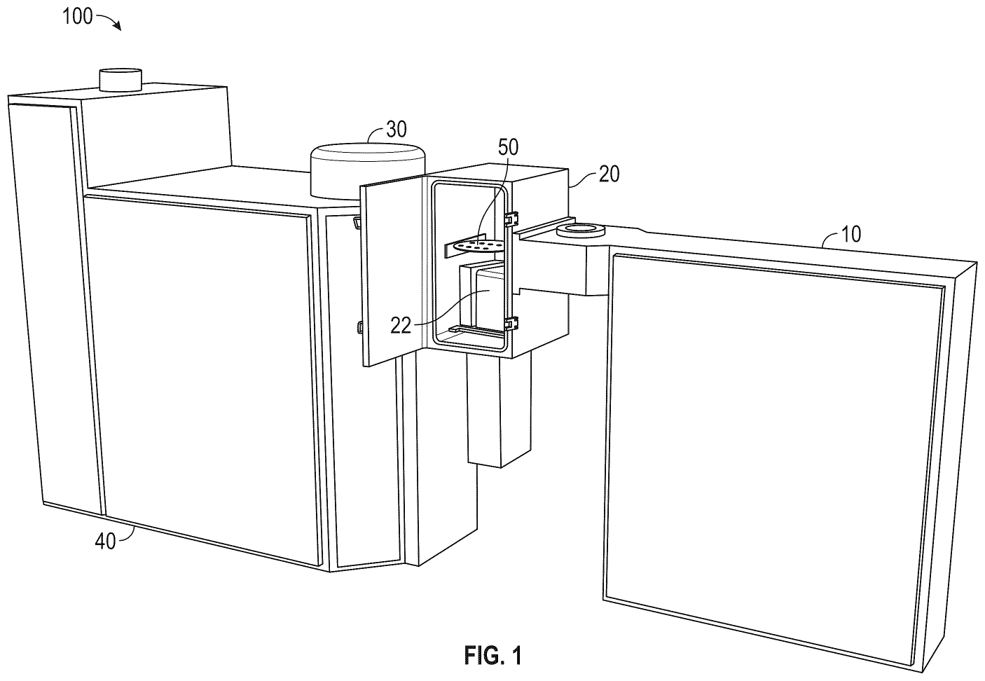

Turning now to FIG. 1, an illustrative system 100 for chemical vapor deposition includes a wafer transport unit 10, a cassette housing 20, a process chamber 30 and a process module 40. Wafer transport unit 10 includes a robotic arm (not shown) and suitable motors (not shown) and controls (not shown) for movement of the robotic arm to allow wafer transport unit 10 to retrieve a wafer 50 from cassette 22 in cassette housing 20, and deliver wafer 50 to process chamber 30. Process module 40 includes heating and cooling systems, gasses for CVD deposition process, one or more plasma generators, a vacuum system, exhaust structures, etc. typically found in CVD systems. The one or more plasma generators may generate one or more of: DC plasma, pulsed DC plasma, RF plasma, pulsed RF plasma, intermediate frequency (IF) plasma, pulsed IF plasma, mixed DC and RF plasma, mixed DC and IF plasma, mixed IF and RF plasma, mixed DC and RF and IF plasma, microwave plasma, or microwave plasma mixed with one or more of DC, RF, or IF plasma. In embodiments, a “pulsed DC” source may be employed to create plasma with constant electric field orientation with optional on/off cycling (unlike RF plasma, where polarity is switching during one oscillation period). Process module 40 also includes controller(s) to control the various functions of the CVD system.

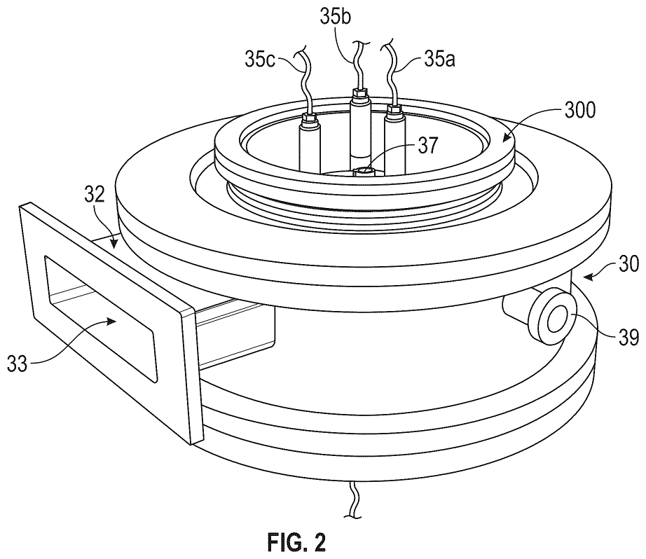

As seen in FIG. 2, process chamber 30 includes a flange 32 including an opening 33 through which wafer 50 is introduced by wafer transport unit 10 into process chamber 30. A valve (not shown) seals process chamber 30 after introduction of wafer 50 as is known to those skilled in the art. A showerhead 300 is mounted to process chamber 30. Sensors 35a, 35b and 35c are mounted through showerhead 300 to detect the temperature of the wafer 50. In embodiments, sensors 35a-c are optical pyrometers that can sense a temperature of wafer 50 as it rotates, without requiring direct contact with wafer 50. A gas inlet port 37 is also provided to permit introduction of process gas (e.g., premixed gases required for CVD deposition of a film onto a substrate) into process chamber 30. Process chamber 30 also includes a view port 39 and a port (not shown) to remove exhaust gasses from process chamber 30.

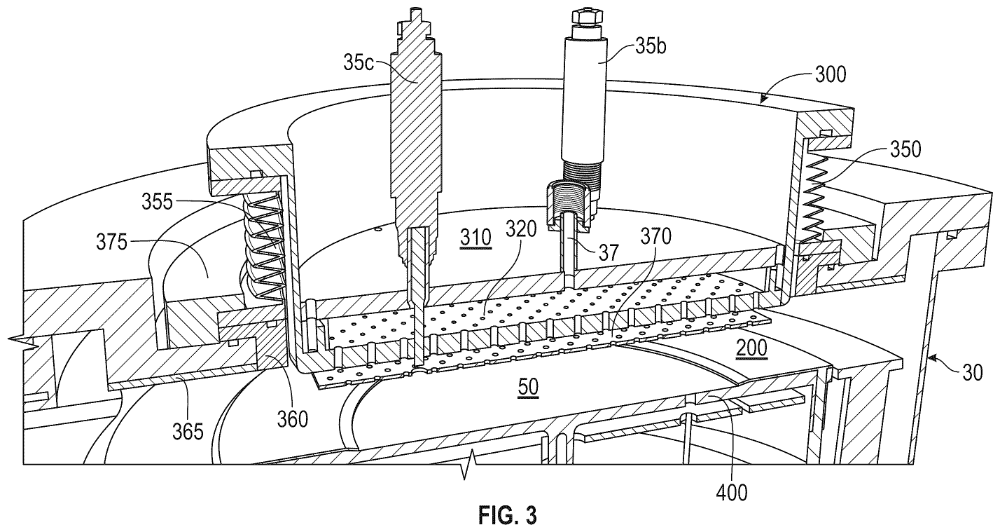

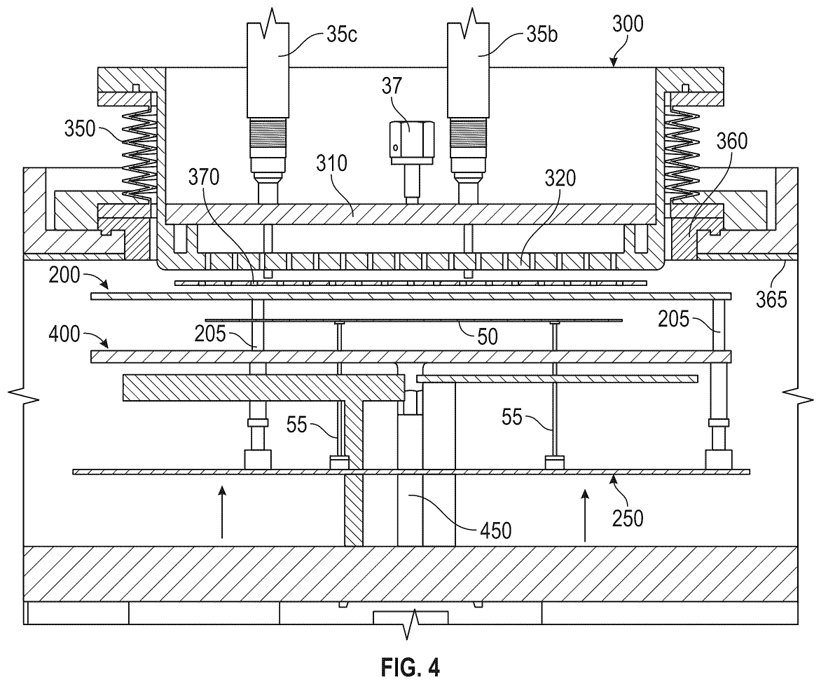

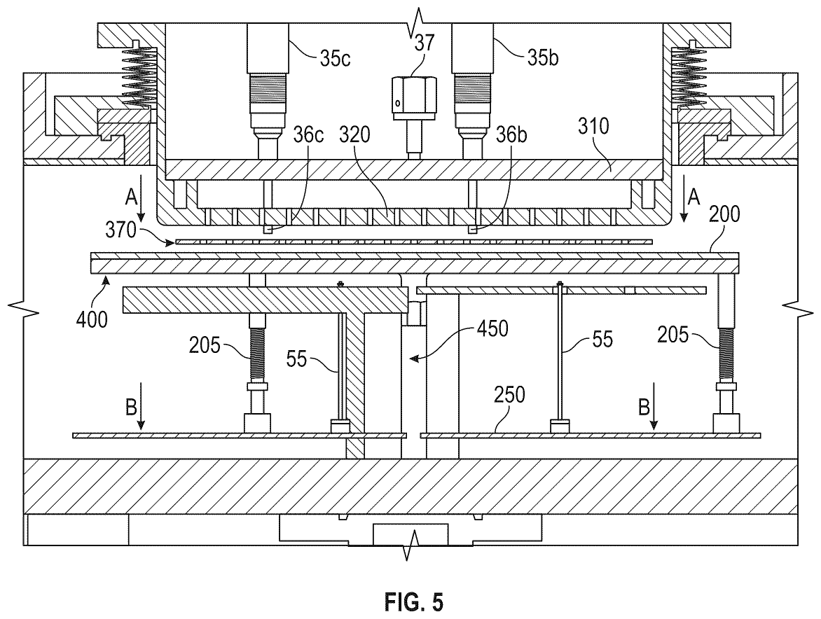

Showerhead 300, shown in detail in FIG. 3, is typically made of a metal (e.g., aluminum) and includes a seal plate 310 through which gas inlet port 37 and sensors 35a-c pass. Sensors 35a-c are positioned through seal plate 310 at different radial positions to measure temperatures at different diameters of the wafer and minimize the impact of gas turbulence around sensors 35a-c. A showerhead plenum 320 is formed by the seal plate 310 and the showerhead 300. Sensors 35a-c pass through showerhead plenum 320, while gas inlet port 37 does not penetrate plenum 320, but rather delivers gas into the space below seal plate 310 (plenum 320). Larger openings are provided through the bottom of showerhead 300 to accommodate the light pipes 36b, 36c (FIG. 5), respectively of sensors 35b, 35c (as well of sensor 35a, although not shown in this view). Bellows 350 are provided to maintain a vacuum seal between the showerhead 300 and process chamber 30 as the position of the showerhead 300 moves from a retracted position (shown in FIG. 4) to a lowered position (shown in FIG. 5). A purge space 355 is provided between bellows 350 and showerhead 300 to prevent material deposition and maintain vacuum leak integrity of the process chamber. Showerhead insulating ring 360 is made of an electrically insulating material (e.g., ceramic or quartz) and, along with ceramic plate 365, helps prevent arcing between showerhead 300 and process chamber 30. Clamping ring 375 for the bellows 350 is made from an insulator to isolate the electrically hot showerhead 300 from the grounded chamber and lid. Showerhead grid electrode 370 includes openings that are larger than the openings in plenum 320. Larger openings are provided through grid electrode 370 to accommodate the light pipes 36b, 36c, respectively of sensors 35b, 35c (as well of sensor 35a, although not shown in this view). Gas delivered below seal plate 310 passes through plenum 320 and then through grid electrode 370 where, under appropriate conditions, plasma is formed and a desired coating may be deposited on wafer 50. The structure shown helps ensure that if deposition of coating occurs other than on the wafer, it occurs on grid 370 rather than on plenum 320. In this way, grid 370 may function as a sacrificial surface, thereby preserving plenum 320.

FIG. 4 shows the process chamber of the system of FIG. 1 with showerhead 300 retracted and wafer 50 and wafer grounding ring 200 in the wafer unload position. Wafer grounding ring 200 is raised by lift pins 205 to provide a space (between wafer grounding ring 200 and rotation chuck 400) into which wafer 50 may be positioned onto wafer lift pins 55. Lift pins 205, 55 are mounted to lift plate 250 and pass though rotation chuck 400 in the raised position, but are clear of rotation chuck 400 when lowered, thereby allowing for rotation of rotation chuck 400, grounding ring 200, and wafer 50 when shaft 450 is driven by a motor (not shown).

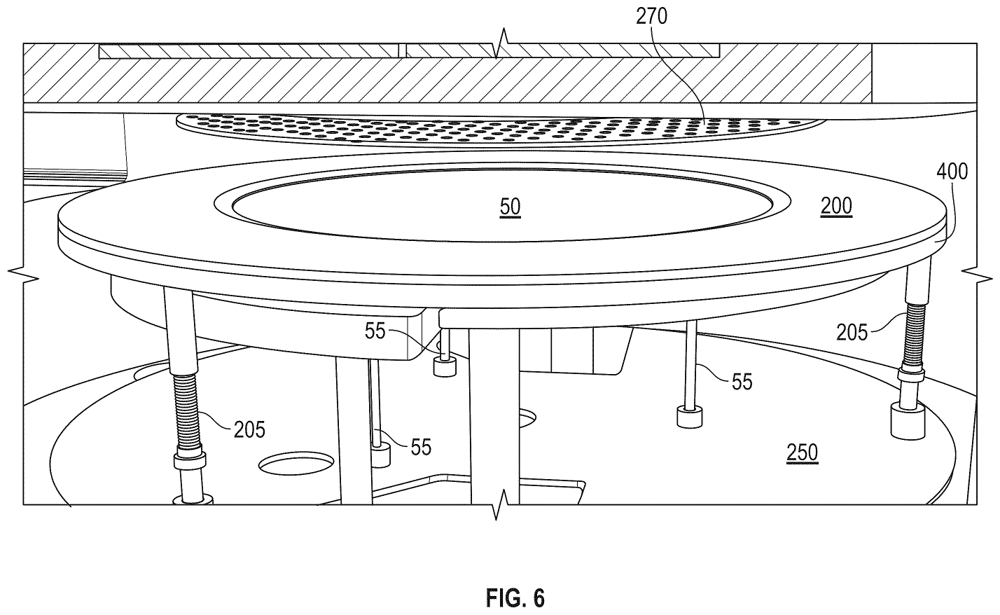

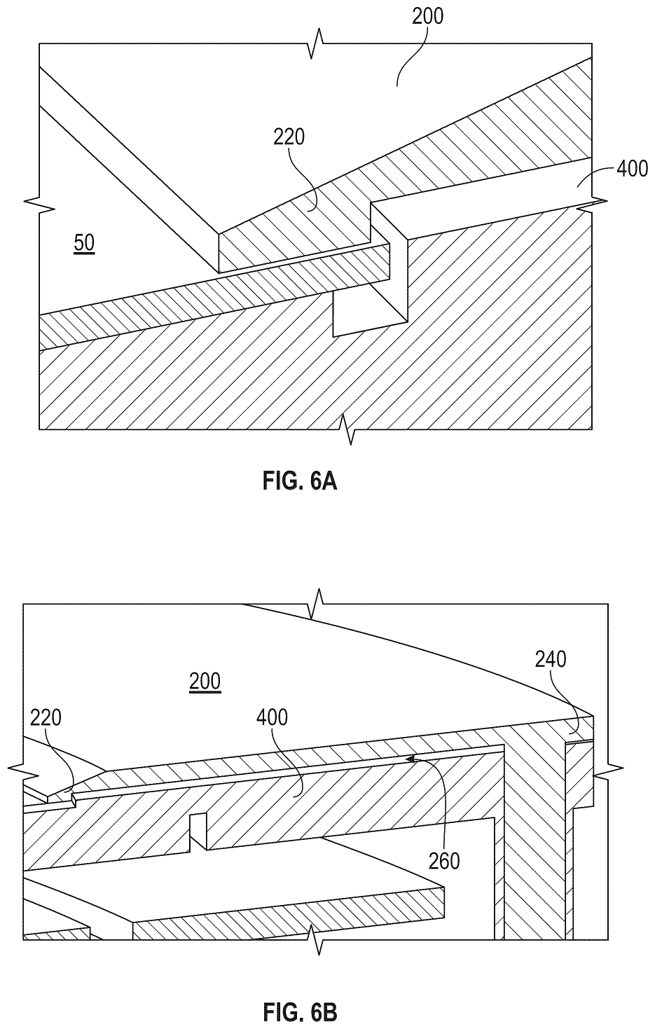

As seen in FIG. 5, when the deposition process is conducted, showerhead 300 is lowered (moved in the direction of arrows “A”), thereby compressing bellows 350 and reducing the space between grid 370 and rotation chuck 400. In addition, wafer grounding ring 200 is lowered into contact with wafer 50 and rotation chuck 400 by moving lift plate 250 in the direction of arrows “B”, thereby grounding wafer 50 for coating by the deposition process. See also, FIG. 6.

When wafer grounding ring 200 is lowered into contact with wafer 50, contact therebetween occurs at annular protrusion 220 at the inner periphery of wafer grounding ring 200, protecting the edge of wafer 50 from arcing by clamping wafer 50 against rotation chuck 400, as shown in FIGS. 6A and B. Contact between wafer grounding ring 200 and rotation chuck 400 occurs at annular protrusion 240 at the outer periphery of wafer grounding ring 200, as show in in FIG. 6B. A space 260 is thereby created between the center portion of wafer grounding ring 200 and rotation chuck 400 when the wafer grounding ring is in the process position. Two contact surfaces 220 and 240 provide full and uniform electrical contact between a wafer, a grounding ring and a chuck. Open gap 260 between a grounding ring 200 and a chuck 400 ensures that flatness and roughness of both parts surfaces does not impede full electrical contact.

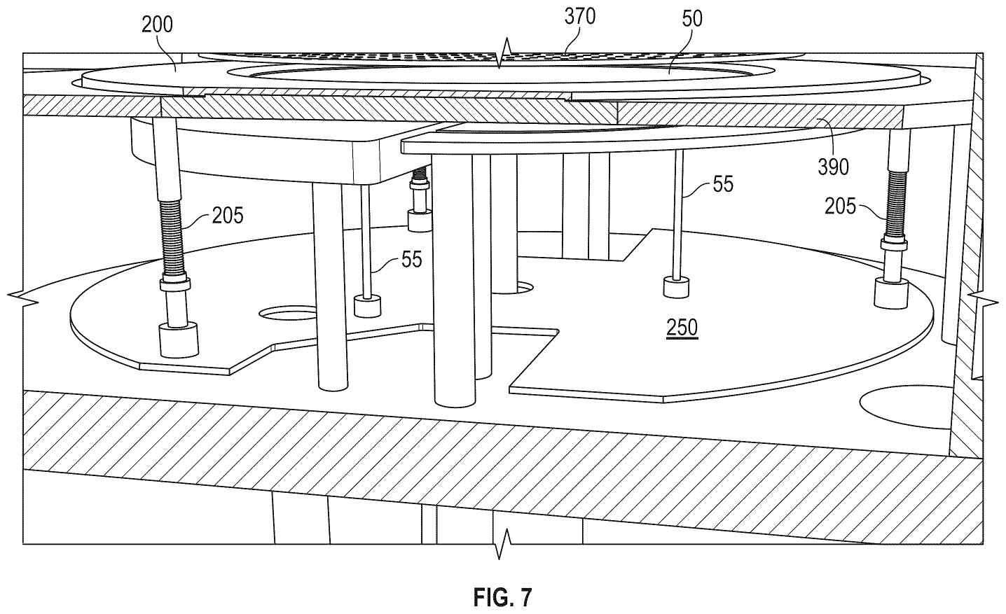

FIG. 7. shows an alternate embodiment where process chamber 300 includes a lower sealing plate 390 which separates lift plate 250 and lift pins 205, 55 from the area where active coating deposition is being carried out.

Systems and apparatus for controlling a temperature of a rotating wafer chuck of a chemical vapor deposition system (such as, for example, a parallel-plate plasma enhanced chemical vapor deposition system) will now be described. In the following description, for purposes of explanation, numerous specific details are set forth in order to provide a thorough understanding of the present disclosure. It will be evident, however, to one skilled in the art that the present disclosure may be practiced without these specific details.

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

The CVD systems of the present disclosure include a rotating wafer chuck that includes at least one rotationally divided heat zone in communication with a heating element and at least one rotationally divided cool zone in communication with a cooling element. Heat from the heating element at the heat zone may increase a temperature of the rotating wafer chuck. Cool from the cooling element may decrease a temperature of the rotating wafer chuck. A system for controlling a temperature of the rotating wafer chuck may include the rotating wafer chuck, a cooling element, a heating element, and a programmable logic controller. The programmable logic controller is in communication with the cooling element, the heating element, and the rotating wafer chuck. The programmable logic controller includes a processor and a memory storing instructions which, when executed by the processor, controls a temperature of the rotating wafer chuck utilizing at least one of the heating element and/or the cooling element and the temperature sensors.

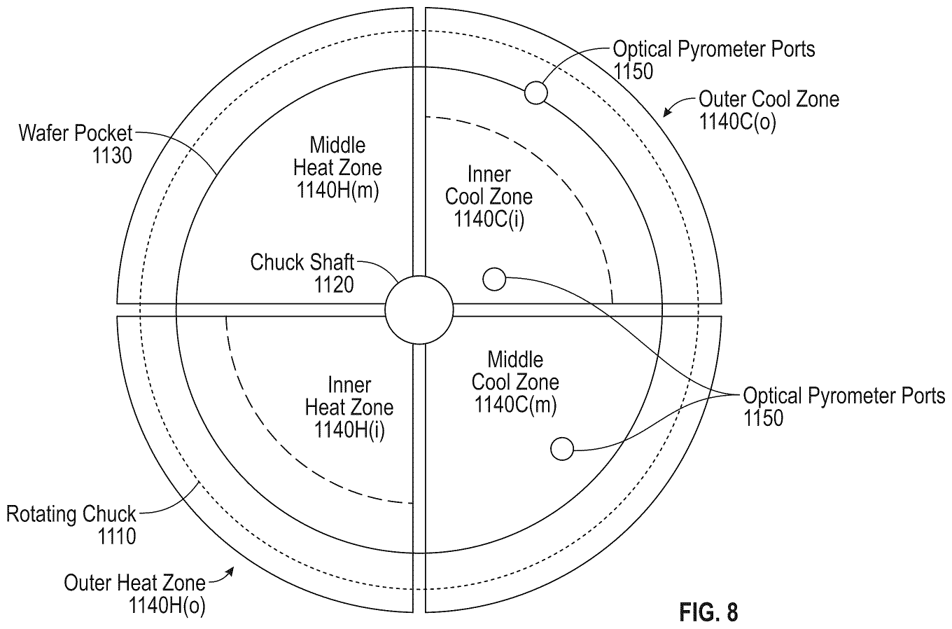

FIG. 8 schematically illustrates a backside view of a rotating wafer chuck according to the present disclosure, arranged in accordance with at least some embodiments presented herein. In the example shown in FIG. 8, a back side of rotating wafer chuck 1110 is shown. Back side of rotating wafer chuck 1110 may include a chuck shaft 1120. Rotating wafer chuck 1110 may be SiC coated graphite and may support a wafer during a plasma enhanced chemical vapor deposition (PECVD) or other chemical vapor deposition process. A location of a wafer pocket 1130 (located on the front side of rotating wafer chuck 1110) is indicated on the back side of rotating wafer chuck 1110.

Back side temperature control of rotating wafer chuck 1110 may be divided into “quadrants”, “pie-shapes” or other rotationally divided zones. In FIG. 8, back side temperature control of rotating wafer chuck 1110 may be divided into six non-contact zones, inner heat zone 1140H(i), middle heat zone 1140H(m), outer heat zone 1140H(o), inner cool zone 1140C(i), middle cool zone 1140C(m), and outer cool zone 1140C(o). While illustrated as having six zones, it should be understood that the back side temperature control of rotating wafer chuck 1110 may be divided into any desired number of zones, which may be more or less than six zones. Optical pyrometer ports 1150 through cool zones 1140C(i), 1140C(m), and 1140C(o) allow the optical pyrometers 35a-c to view rotating wafer chuck 1110, thus allowing the PLC 1190 to control chuck temperature, via adjusting respective heating and cooling zones. Back side of rotating wafer chuck 1110 may be both heated and cooled simultaneously and may have separate multiple heating and cooling zones. In embodiments, the system may include one or more “top-side” optical pyrometers (as shown in the drawings), one or more “bottom-side” optical pyrometers (not shown), or a combination of “bottom-side” and “top-side” optical pyrometers.

Heat zones 1140H(i), 1140H(m), and 1140H(o), and cool zones 1140C(i), 1140C(m), and 1140C(o) may be concentrated on different radial areas of rotating wafer chuck 1110 to focus on particular heat loss or heat gain regions such as edge heat loss, shaft heat loss proximate to the coupling, areas facing heated elements, areas in proximity to hot gas streams, areas in proximity to plasma sources, etc.

Heat zones 1140H(i), 1140H(m), and 1140H(o), and cool zones 1140C(i), 1140C(m), and 1140C(o) may be thermally averaged by the rotating mass of rotating wafer chuck 1110. A rotational rate of >=10 RPM of rotating wafer chuck 1110 may be sufficient to “smooth out” heating and cooling variations within rotating wafer chuck 1110 and may represent a cycle time of 1.5 seconds on a 4-quadrant design and be similar to typical time-proportioned heating systems.

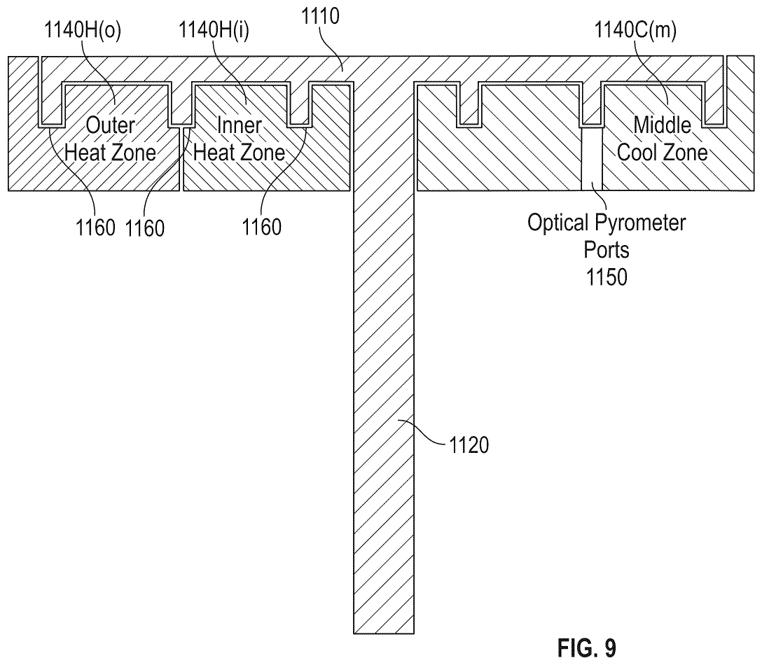

FIG. 9 illustrates a side cross sectional view of a rotating wafer chuck according to the present disclosure, arranged in accordance with at least some embodiments presented herein, and shows inner heat zone 1140H(i) and outer heat zone 1140H(o) on a first side of rotating wafer chuck 1110 and middle cool zone 1140C(m) on a second side of rotating wafer chuck 1110. Middle cool zone 1140C(m) of rotating wafer chuck 1110 may include optical pyrometer port 1150. Rotating wafer chuck 1110 may include chuck fins 1160 which may increase heat transfer to rotating wafer chuck 1110 by interfacing with inner heat zone 1140H(i) and outer heat zone 1140H(o) and middle cool zone 1140C(m) (other zones not shown).

Inner heat zone 1140H(i), outer heat zone 1140H(o), along with middle heating zone 1140H(m) (from FIG. 8) may be heated by heating elements utilizing any heating technique, including, but not limited to: (1) radiant heating including graphite resistance, infrared (IR) lamps (i.e.: miniature bulbs with gold reflectors), ceramic resistance, a tubular heater (e.g., calrod-style), and printed-metal resistance; (2) convective heating (with coupling gas flow) including graphite resistance, ceramic resistance, a tubular heater (Calrod™-style), and printed-metal resistance; and (3) induction heating including RF magnetic coils may be shaped into creating effective heating zones in different areas of rotating wafer chuck 1110. Direct conduction heating may not be practical under some circumstances for heating rotating wafer chuck 1110 due to the rotating non-contact nature of rotating wafer chuck 1110 and conduction heating may be performed through the use of coupling gas flow.

Graphite resistance heating elements may be used with rotating wafer chuck 1110 and may be easily tailored to fit specific shapes to create a desired heating effect and zoning within rotating wafer chuck 1110. Graphite resistance heating elements may be compatible with the process environment, or may need to be kept purged by inert gas to prevent degradation.

Middle cool zone 1140C(m) along with inner cool zone 1140C(i) and outer cool zone 1140C(o) may be cooled by cooling elements utilizing any cooling technique, including, but not limited to: (1) radiant cooling including liquid-cooled metal (Copper, Aluminum, Nickel, or suitable Alloy) plate (optionally coated with dark material for high absorptive emissivity); and (2) convective cooling (with coupling gas flow) including liquid-cooled metal (Copper, Aluminum, Nickel, or suitable Alloy) plate (optionally coated with dark material for high emissivity). Direct conduction cooling may not be practical under some circumstances for cooling rotating wafer chuck 1110 due to the rotating non-contact nature of rotating wafer chuck 1110, and conduction cooling may be performed through the use of coupling gas flow.

Cooling techniques may use water or oil-based liquid loops. During heating cycles, cooling elements may need to be kept at an elevated temperature to reduce heat losses from rotating wafer chuck 1110. Cooling techniques may utilize an embedded-heater water or oil path (e.g., CAST-X™ style) to produce a desired temperature of rotating wafer chuck 1110. In embodiments where a temperature of a cooling zone 1140C(i), 1140C(m), or 1140C(o) is to exceed 120° C. during heating, oil may be used.

When rapid cooling from a desired process temperature is desired, a refrigerating chiller, or liquid/liquid heat exchanger may be employed to lower a cooling element temperature quickly. When fast-cycle times occur, valves may be used to switch a cooling element between hot-liquid and cold-liquid loops which may each be pre-maintained at a respective desired temperature. When multiple cooling zones are utilized, a temperature of each zone (for example zones 1140C(i), 1140C(m), and 1140C(o)) may be regulated by modulating a flow between hot and cold liquid cooling loops.

As shown in FIGS. 8 and 9, optical pyrometer ports 1150 may be present to allow direct view of rotating wafer chuck 1110 to measure a temperature in each cooling zone 1140C(i), 1140C(m), and 1140C(o). Direct temperature measurement in each cooling zone 1140C(i), 1140C(m), and 1140C(o) can be utilized to provide closed-loop control of a temperature of rotating wafer chuck 1110 and control the temperature uniformly across the radius of rotating wafer chuck 1110 from inner center to outer diameter. Alternately, a custom temperature profile for rotating wafer chuck 1110 may be created by intentionally setting cooling zones 1140C(i), 1140C(m), and 1140C(o) at different temperatures.

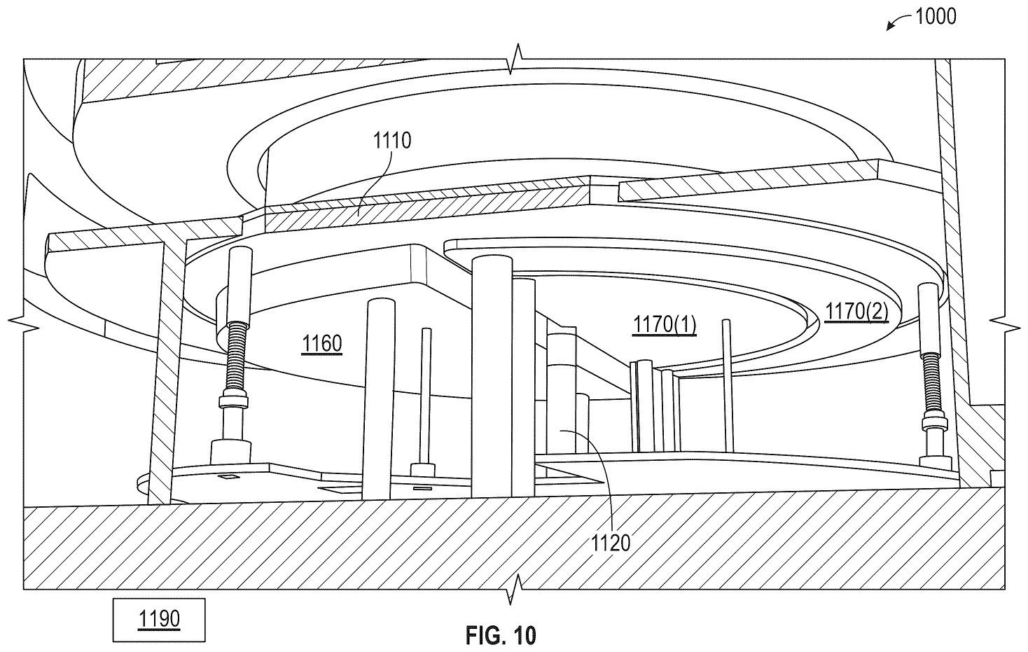

FIG. 10 illustrates a bottom perspective view of an example system for cooling a rotating wafer chuck according to the present disclosure, arranged in accordance with at least some embodiments presented herein. System 1000 may be a heating/cooling system and may include rotating wafer chuck 1110, a cooling element 1160, a heating element 1170, and a programmable logic controller (PLC) 1190. Cooling element 1160 may be a cooling plate. Heating element 1170 may be a two zone SiC coated graphite heater with a first heating zone 1170(1) and a second heating zone 1170(2). PLC 1190 may be in communication with cooling element 1160, heating element 1170, and rotating wafer chuck 1110 including optical pyrometer ports 1150 to receive direct temperature measurement in each cooling zone 1140C(i), 1140C(m), and 1140C(o) of FIGS. 9 and 10.

PLC 1190 may include a processor and a memory storing instructions that, when executed by the processor, may select heating-only, cooling-only or combined heating/cooling modes, depending on the desired temperature ramp profile (e.g., heatup, temperature maintenance, cooldown). Likewise, instructions included in PLC 1190 may determine a proper cooling element temperature (e.g., maximum cooling, elevated temperature, or modulating temperature) to quickly stabilize a temperature of rotating wafer chuck 1110 and to respond to environmental changes (e.g., plasma on/off, heated gas, vacuum pressure, gas flow changes, etc.).

In some embodiments, PLC 1190 may execute an algorithm to stabilize a temperature of rotating wafer chuck 1110 during PECVD by controlling heating elements 1170 with active and passive temperature control. In some embodiments, PLC 1190 may execute an algorithm to utilize heating elements 1170 to increase a temperature of rotating wafer chuck 1110 or cooling elements 1160 to decrease a temperature of rotating wafer chuck 1110. In some embodiments, PLC 1190 may execute an algorithm to utilize heating elements 1170 and cooling elements 1160 working together simultaneously for quick, precise temperature control of rotating wafer chuck 1110. PLC 1190 may execute an algorithm to utilize heating elements 1170 and cooling elements 1160 may work together simultaneously when ambient conditions alone do not supply enough cooling for good temperature regulation of rotating wafer chuck 1110 (e.g., slow thermal cooling response+fast heating response=difficult to tune temperature control loop). As temperature control of cooling elements may be effective only over a limited temperature range and cooling capacity may be limited, in some embodiments, PLC 1190 may execute an algorithm to set cooling elements 1160 to a “constant temperature” or “constant power” setting and may modulate heating elements 1170 with enough power to overcome the cooling effect of cooling elements 1160. Other variations of heating and cooling profiles are contemplated by this disclosure and will be apparent to one skilled in the art reading this disclosure.

Different temperature zones 1140H(i), 1140H(m), 1140H(o), 1140C(i), 1140C(m), and 1140C(o) (shown in FIGS. 8 and 9) may require PLC 1190 to utilize different heating/cooling strategies at different times, depending upon the thermal conditions desired. Slow vs. fast heating ramp-up may require different heating/cooling strategies. Low temperature operation may require PLC 1190 to utilize different heating/cooling strategies from high temperature operation. The flexibility of heating/cooling system 100 may provide a strategy for PLC 1190 to control a temperature for rotating wafer chuck 1110 as needed for the conditions required.

In some embodiments when additional heating/cooling energy density is required, circular “fins” or chuck fins 1160 may be designed into rotating wafer chuck 1110 with matching “pockets” fabricated into heating/cooling elements 1170, 1160 which may create more surface area for direct radiation of heat energy, and also provide additional surface area for gas convective heat transfer.

Convective heat transfer may be particularly useful for enhanced cooling function, due to the low differential temperatures between rotating wafer chuck 1110 and cooling elements 1160. High thermal conductivity gases such as Helium may be used for convective cooling of wafers and rotating wafer chuck 1110. Cooling to ambient temperature may happen following deposition process steps, and addition of Helium gas flow during a cooling step may not tend to disrupt the deposition processes. When additional cooling is needed during process deposition steps, a cooling gas path may be constructed to avoid gas mixing within the deposition zone.

While parallel-plate PECVD reactor temperature control has been disclosed, it is contemplated that the novel heating/cooling system may be utilized in many different applications where there is a rotating component that needs to be heated and cooled. The system may be especially suitable to “flat” rotating surfaces found in cluster tool (and non-cluster) process chambers for metal organic chemical vapor deposition (MOCVD), atomic layer deposition (ALD), low pressure chemical vapor deposition (LPCVD), physical vapor deposition (PVD), annealing, heat treating, plasma etching and other similar processes involving elevated temperatures which require temperature uniformity and rapid cooling for high-throughput. The described rotary temperature control technique may also be applicable to larger, non-planar processed parts, when rotary motion is involved to create rotationally-symmetrical temperature control.

Also, while described in terms of depositing a coating on a wafer, it should be understood that the present systems may be used to provide a coating on any suitable substrate.

The systems described herein may utilize one or more controllers to receive various information and transform the received information to generate an output. The controller may include any type of computing device, computational circuit, or any type of processor or processing circuit capable of executing a series of instructions that are stored in a memory. The controller may include multiple processors and/or multicore central processing units (CPUs) and may include any type of processor, such as a microprocessor, digital signal processor, microcontroller, programmable logic device (PLD), field programmable gate array (FPGA), or the like. The controller may also include a memory to store data and/or instructions that, when executed by the one or more processors, causes the one or more processors to perform one or more methods and/or algorithms.

Any of the herein described methods, programs, algorithms or codes may be converted to, or expressed in, a programming language or computer program. The terms “programming language” and “computer program,” as used herein, each include any language used to specify instructions to a computer, and include (but is not limited to) the following languages and their derivatives: Assembler, Basic, Batch files, BCPL, C, C+, C++, Ladder Logic, Delphi, Fortran, Java, JavaScript, machine code, operating system command languages, Pascal, Perl, PL1, scripting languages, Visual Basic, metalanguages which themselves specify programs, and all first, second, third, fourth, fifth, or further generation computer languages. Also included are database and other data schemas, and any other meta-languages. No distinction is made between languages which are interpreted, compiled, or use both compiled and interpreted approaches. No distinction is made between compiled and source versions of a program. Thus, reference to a program, where the programming language could exist in more than one state (such as source, compiled, object, or linked) is a reference to any and all such states. Reference to a program may encompass the actual instructions and/or the intent of those instructions.

The storage and/or memory device may be one or more physical apparatus used to store data or programs on a temporary or permanent basis. In some embodiments, the controller may include volatile memory and requires power to maintain stored information. In some embodiments, the controller includes non-volatile memory and retains stored information when it is not powered. In some embodiments, the non-volatile memory includes flash memory. In some embodiments, the non-volatile memory includes dynamic random-access memory (DRAM). In some embodiments, the non-volatile memory includes ferroelectric random access memory (FRAM). In some embodiments, the nonvolatile memory includes phase-change random access memory (PRAM). In some embodiments, the controller is a storage device including, by way of non-limiting examples, CD-ROMs, DVDs, flash memory devices, magnetic disk drives, magnetic tapes drives, optical disk drives, and cloud computing based storage. In some embodiments, the storage and/or memory device is a combination of devices such as those disclosed herein. Code or instructions contained thereon can be represented by carrier wave signals, infrared signals, digital signals, and by other like signals.

It should be understood that the foregoing description is only illustrative of the present disclosure. Various alternatives and modifications can be devised by those skilled in the art without departing from the disclosure. Accordingly, the present disclosure is intended to embrace all such alternatives, modifications and variances. The embodiments described with reference to the attached drawing figures are presented only to demonstrate certain examples of the disclosure. Other elements, steps, methods, and techniques that are insubstantially different from those described above and/or in the appended claims are also intended to be within the scope of the disclosure.

1. A temperature control apparatus, the apparatus comprising; a rotating wafer chuck including:
at least one rotationally divided heat zone in communication with a heating element, the at least one rotationally divided heat zone located adjacent a first portion of a wafer supported on the rotating wafer chuck; and
at least one rotationally divided cool zone in communication with a cooling element, the at least one rotationally divided cool zone located adjacent a second, different portion of the wafer supported on the rotating wafer chuck.

2. The apparatus of claim 1, wherein the rotating wafer chuck includes an inner heat zone and an outer heat zone.

3. (canceled)

4. (canceled)

5. A system for controlling a temperature during chemical vapor deposition, the system comprising:
a rotating wafer chuck;
a cooling element;
a heating element; and
a programmable logic controller, wherein:
the rotating wafer chuck includes at least one rotationally divided heat zone in communication with the heating element, the at least one rotationally divided heat zone located adjacent a first portion of a wafer supported on the rotating wafer chuck, and at least one rotationally divided cool zone in communication with the cooling element, the at least one rotationally divided cool zone located adjacent a second, different portion of the wafer supported on the rotating wafer chuck,
the programmable logic controller is in communication with the cooling element, the heating element, and the rotating wafer chuck, and
the programmable logic controller includes a processor and a memory storing instructions which, when executed by the processor, control a temperature of the rotating wafer chuck utilizing at least one of the heating element or the cooling element.

6. The system of claim 5 wherein the instructions, when executed by the processor, controls a temperature of the rotating wafer chuck utilizing the heating element and the cooling element simultaneously.

7. The system of claim 5 wherein the instructions, when executed by the processor, sets the cooling element to a constant temperature or constant power setting and modulates the heating element with enough power to overcome the cooling effect of the cooling element.

8. The system of claim 5, wherein the rotating wafer chuck comprises graphite coated with SiC.

9. The system of claim 5, wherein the cooling element is a cooling plate.

10. The system of claim 5, wherein the heating element comprises a two zone graphite heater coated with SiC.

11. A method of stabilizing the temperature of a rotating wafer chuck of a chemical vapor deposition system during chemical vapor deposition, the method comprising:
rotating a substrate to be coated in a rotating wafer chuck,
measuring the temperature of the substrate in two or more different rotationally divided zones of the rotating wafer chuck; and
adjusting the temperature of the rotating wafer chuck by automatically activating a heating element located adjacent a first portion of the substrate, a cooling element located adjacent a second, different portion of the substrate, or both.

12. The method of claim 11, wherein measuring the temperature in of the substrate comprises measuring the temperature at three different locations from above the substrate.

13. The method of claim 11, wherein measuring the temperature of the substrate comprises measuring the temperature using non-contact temperature sensors.

14. The method of claim 11, wherein measuring the temperature of the substrate comprises measuring the temperature using a plurality of optical pyrometers.

15. The method of claim 11, wherein the chemical vapor deposition system includes a processor and a memory storing instructions which, when executed by the processor, cause the adjusting of the temperature of the rotating wafer chuck by:
receiving temperature measurements of two or more different rotationally divided zones of the rotating wafer chuck; and
based on the received temperature measurements, activating the heating element, the cooling element, or both to change the temperature in one or more of the rotationally divided zones.

16. The method of claim 15, wherein the instructions, when executed by the processor, cause the adjusting of the temperature of the rotating wafer chuck to a uniform temperature across the radius of rotating wafer chuck.

17. The method of claim 15, wherein the instructions, when executed by the processor, cause the adjusting of the temperature of the rotating wafer chuck to a predetermined temperature profile across the radius of rotating wafer chuck.

18. (canceled)

19. The method of claim 17, wherein the instructions, when executed by the processor, cause the adjusting of the temperature of the rotating chuck to a temperature profile of different temperatures in an inner heat zone and an outer heat zone.

20. The method of claim 17, wherein, during chemical vapor deposition, the chemical vapor deposition system generates one or more of: DC plasma, pulsed DC plasma, RF plasma, pulsed RF plasma, intermediate frequency (IF) plasma, pulsed IF plasma, mixed DC and RF plasma, mixed DC and IF plasma, mixed IF and RF plasma, mixed DC and RF and IF plasma, microwave plasma, or microwave plasma mixed with one or more of DC, RF, or IF plasma.

21. The method of claim 15, wherein the instructions, when executed by the processor, cause the adjusting of the temperature of the rotating wafer chuck using the cooling element in response to plasma being turned on or off.

22. The system of claim 5 wherein the instructions, when executed by the processor, control a temperature of the rotating wafer chuck, based on signals from two or more sensors positioned over a wafer supported on the rotating wafer chuck.

23. The system of claim 5 wherein the instructions, when executed by the processor, control a temperature of the rotating wafer chuck based on signals from a plurality of sensors positioned over a wafer supported on the rotating wafer chuck, and at least one sensor positioned below the rotating wafer chuck.
